(19) United States
(12) Patent Application Publication
(10) Pub. No.: US 2014/0334109 A1
(43) Pub. Date: Nov. 13, 2014

(54) Electronic Component Module and Method of Manufacturing the Same

(71) Applicant: Yazaki Corporation, Minato-ku, Tokyo (JP)

(72) Inventor: Yusuke Takagi, Makinohara-shi (JP)

(73) Assignee: YAZAKI CORPORATION, Minato-ku, Tokyo (JP)

(21) Appl. No.: 14/360,175

(22) PCT Filed: Nov. 22, 2012
(86) PCT No.: PCT/JP2012/081006

§ 371 Date: May 22, 2014

(30) Foreign Application Priority Data
Nov. 22, 2011 (JP) 2011-254726

(51) Int. Cl. H05K 1/18; H05K 3/30

(52) U.S. Cl. CPC H05K 1/181; H05K 3/30
USPC 361/728; 427/98.4

(57) ABSTRACT

An electronic component module includes a wiring board on which at least one electronic component is mounted, an outer layer portion that is made of prepreg and covers the wiring board so that all of the at least one mounted electronic component is not exposed, and a terminal portion that is exposed from the outer layer portion to the outside and is configured to electrically connected to a mating connection member.

### TECHNICAL FIELD

The present disclosure relates to an electronic component module and a method of the same, and particularly, to an electronic component module which includes electronic components mounted on a wiring board and has a structure protecting the electronic components.

### BACKGROUND ART

In an electronic component module according to the related art, for example, as shown in an electronic module 100 of FIGS. 5A and 5B, electronic components 110 are mounted on a wiring board 120, and the wiring board 120 is surrounded and protected by a case 150. FIG. 5A is a perspective view illustrating the electronic module 100, and shows internal components (the wiring board 120 and the electronic components 110) by broken lines. Further, terminals 130 for electrically connecting the wiring board 120 with the outside are protruded from the case 150. According to this configuration, the wiring board 120 on which the electronic components 110 is mounted is protected.

Also, in an electronic module 200 of FIGS. 6A and 6B, a wiring board 220 on which electronic components 210 are mounted is covered and protected by a module case 250. FIG. 6A is a perspective view illustrating the electronic module 200, and FIG. 6B is a view illustrating the inside of FIG. 6A by broken lines.

Also, as a technique for protecting electronic components, for example, there is a chip array module in which a plurality of semiconductor chips and a heat sink which are sealed with a sealing body (see PTL (Patent Literature) 1 for instance). In this technique, the heat sink and the semiconductor chips are mounted on a printed wiring board.

### CITATION LIST

### Patent Literature

[PTL 1] JP-A-2003-31742

### SUMMARY OF INVENTION

### Technical Problem

However, if a case or the like is used, the cost of the case, the cost of a mold for forming the case, various processing costs, and the like are incurred, and thus the cost of an electronic module becomes high. Further, in the light of downsizing, other technologies are required. In the technology disclosed in PTL 1, a fluid sealant is stored in a flow tank, and the printed wiring board is soaked in the flow tank, whereby the printed wiring board is covered with the sealant. Therefore, the shape of the sealing body is irregular, and it is impossible to use the sealing body portion for connection with another module or the like.

The present disclosure is made in view of the above-mentioned circumferences, and an object of the present disclosure is to provide a technology solving the above-mentioned problems.

### Solution to Problem

In order to achieve the above object, according to the present invention, there is provided an electronic component module comprising:

a wiring board on which at least one electronic component is mounted;

an outer layer portion that is made of prepreg and covers the wiring board so that all of the at least one mounted electronic component is not exposed; and

a terminal portion that is exposed from the outer layer portion to the outside and is configured to electrically connected to a mating connection member.

For example, a region of the outer layer portion where the terminal portion is exposed becomes a connection structure with the mating connection member.

According to the present invention, there is also provided a method of manufacturing an electronic component module comprising:

providing a wiring board on which at least one electronic component is mounted, and a terminal portion which is electrically connected to the wiring board;

covering a prepreg sheet on the wiring board; and

heating the prepreg sheet to form an outer layer portion so that all of the at least one mounted electronic component is covered with a melted resin and the terminal portion for electrically connecting to a mating connection member is exposed to the outside.

### ADVANTAGEOUS EFFECTS OF INVENTION

According to the present disclosure, it is possible to implement an electronic module which does not use a case as an outer layer and is easily downsized.

### BRIEF DESCRIPTION OF DRAWINGS

FIGS. 1A and 1B are views illustrating an electronic module according to an embodiment.

FIGS. 2A to 2C are views illustrating the electronic module and a mounting device according to the embodiment.

FIGS. 3A and 3B are views illustrating an electronic module according to a modification of the embodiment.

FIGS. 4A and 4B are views illustrating an electronic module according to another modification of the embodiment.

FIGS. 5A and 5B are views illustrating an electronic module according to the related art.

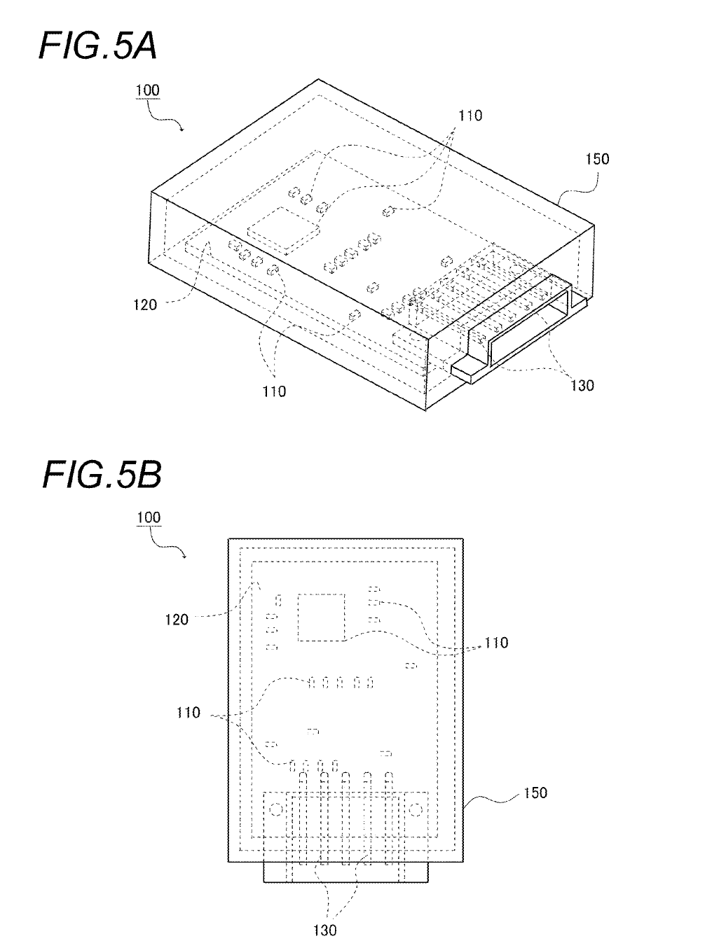

FIGS. 6A and 6B are views illustrating another electronic module according to the related art.

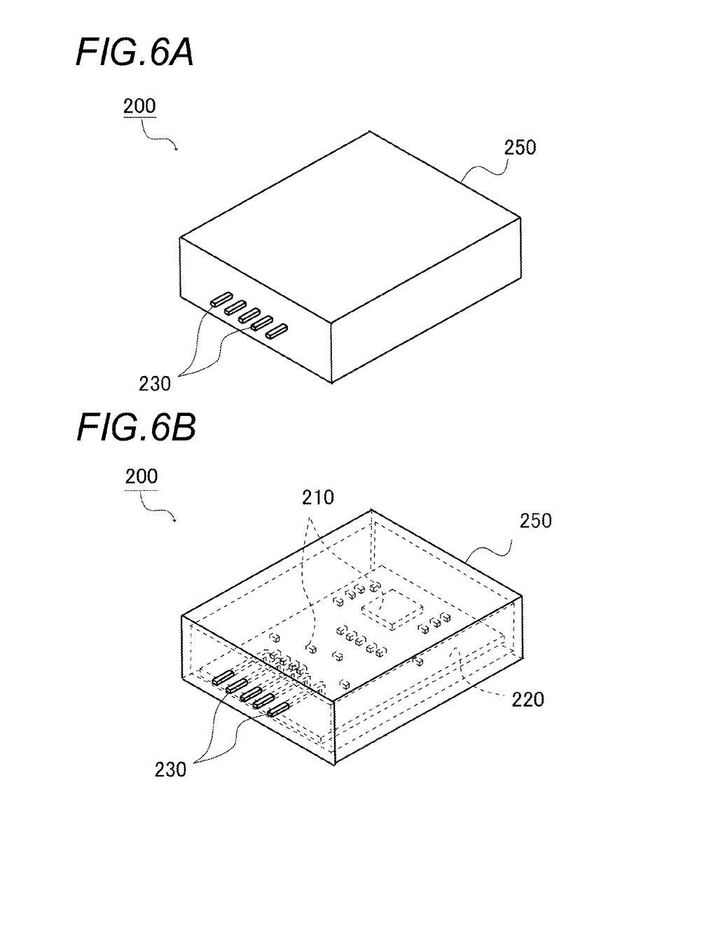

### DESCRIPTION OF EMBODIMENTS

Hereinafter, a mode for embodying the present disclosure (hereinafter, referred to as an “embodiment”) will be described with reference to the accompanying drawings.

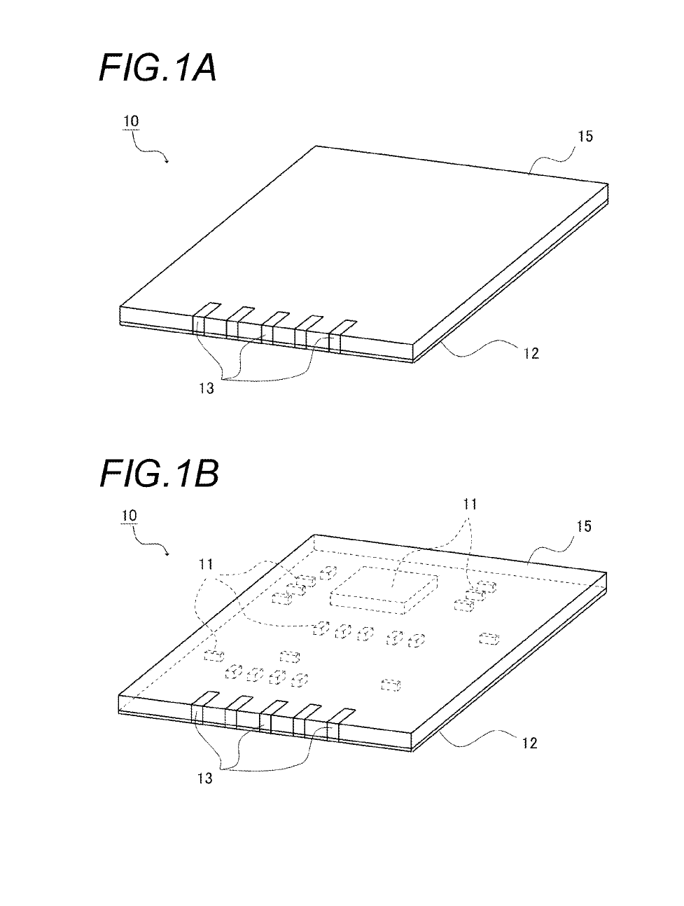

FIGS. 1A and 1B are perspective views illustrating an electronic module 10 according to an embodiment. FIG. 1B is a view illustrating the internal structure (particularly, electronic components 11) of the electronic module 10 of the perspective view of FIG. 1A by some broken lines. The electronic module 10 has a card shape, and includes card edge type connection terminals 13.

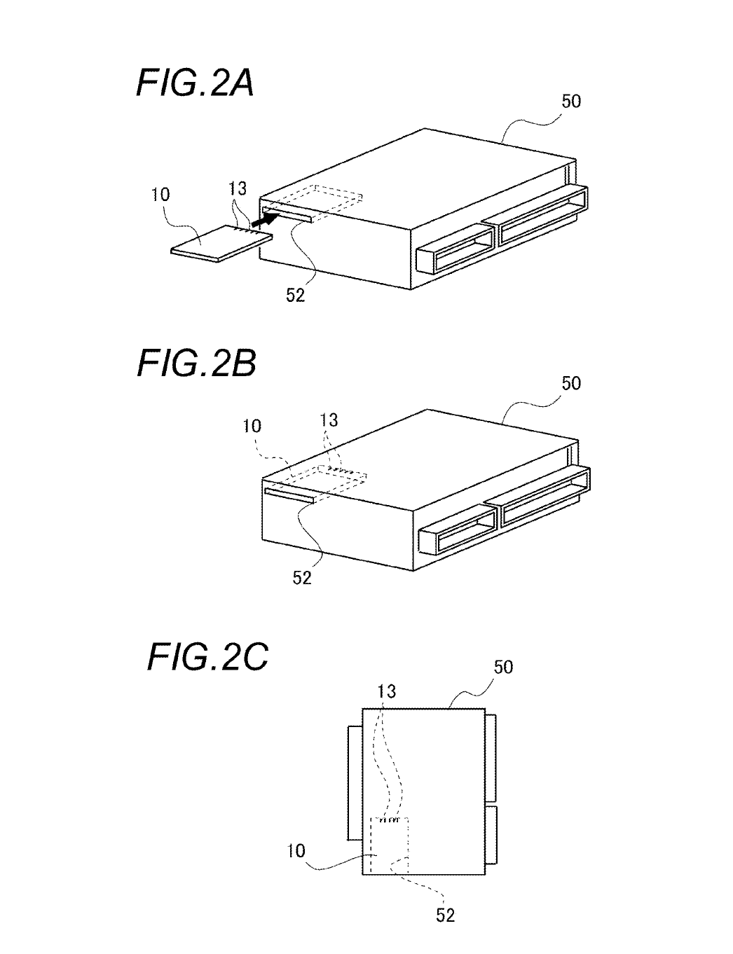

FIGS. 2A to 2C are views illustrating a mounting device 50 including a card accommodating unit 52 into which the card-shaped electronic module 10 is inserted. Specifically, FIG. 2A is a perspective view illustrating a state before the electronic module 10 is inserted into the card accommodating unit 52, FIG. 2B is a perspective view illustrating a state where the electronic module 10 is inserted in the card accommodating unit 52, and FIG. 2C is a plan view illustrating the state where the electronic module 10 is inserted in the card accommodating unit 52.

As shown in FIGS. 1A and 1B, the electronic module 10 includes a wiring board 12, the electronic components 11 mounted on the wiring board 12, the connection terminals 13, and an outer layer portion 15.

The wiring board 12 is, for example, a single-sided mounting board, and uses a rigid substrate as a base substrate. Also, a circuit pattern is formed only on the upper surface of the wiring board 12 shown in FIGS. 1A and 1B, and the electronic components 11 are mounted on the upper surface of the wiring board 12. The wiring board 12 may be a multi-layer board or a double-sided mounting board. In a case of a double-sided mounting board, the outer layer portion 15 is laminated on both surfaces.

The electronic components 11 are chip components such as resistors and capacitors, and integrated circuits (IC). The connection terminals 13 are card edge type terminals for electrical connection with terminals of a mating module.

The outer layer portion 15 is made of prepreg, for example, the prepreg (prepreg sheet) is obtained by impregnating glass cloth with a thermosetting resin such as an epoxy resin. That means, the prepreg is a composite material in which a glass fiber is impregnated with an insulation resin material. In a laminating process method, under vacuum, that prepreg is stuck on the wiring board 12 which is the base substrate from the above, and is pressed and heated. In this process, the thermosetting resin melts by the heating, whereby all electronic components 11 except for the connection terminals 13 are covered with the resin. A region around the connection terminals 13 has a connection structure such that when the region of the connection terminals is accommodated in the card accommodating unit 52 which serves as a mating contact module, the region exactly fits in the shape of the card accommodating unit 52.

Therefore, in the electronic module 10 having the above-mentioned structure, since a case, mold resin, and the like are unnecessary, it is possible to suppress production cost. Also, it is possible to reduce the size by the size of a case and the like omitted. Further, even in a space which is occupied by a connector and the like in the related art, it is possible to mount components. Therefore, the degree of freedom of design such as component disposition is improved, and even from this standpoint, it is possible to implement more effective downsizing.

Also, in a case where the outer layer portion 15 of the electronic module 10 is made of the prepreg like in the present embodiment, it is preferable to form a cuboid shape such as a card shape in view of a manufacturing method and the like.

Also, in a case where circuit patterns such as copper foil are exposed, it is preferable to provide a protecting coating sufficient for maintaining the performance of a resist or the like. However, in a use condition that the electronic module 10 is inserted into the mounting device 50 shown in FIGS. 2A to 2C, if the circuit patterns are sufficiently protected, it is unnecessary to protect the wiring board by a special resist or the like. Also, it is also effective to use a pinching terminal for the card accommodating unit 52 of the mounting device 50.

The present disclosure has been described on the basis of the embodiment. The embodiment is illustrative and it is understood by those skilled in the art that it is possible to make various modifications to those components and their combination and that these modifications are also in the scope of the invention.

For example, prepreg has been exemplified as the outer layer portion 15, but even if a thermosetting resin or a thermoplastic resin is used instead of the prepreg, the same effects are obtained. Also, in forming a connection structure with a mating module as described above, the prepreg is most preferable.

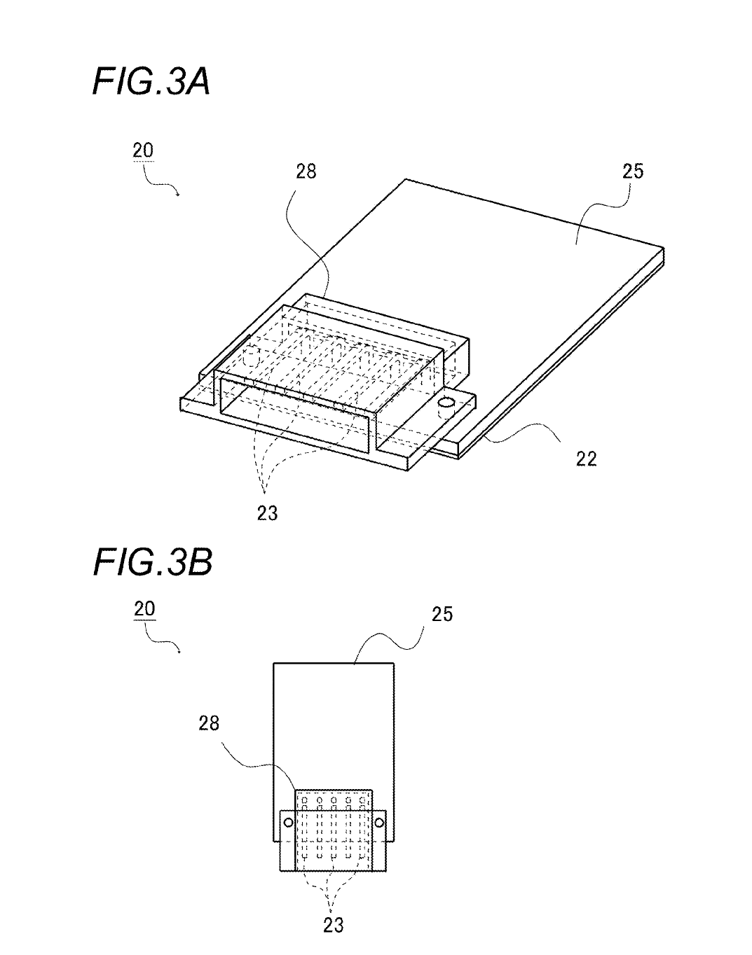

Also, for example, in the above-mentioned embodiment, a form in which a card edge connector is used for the electronic module 10 has been exemplified. However, the present disclosure is not limited thereto. For example, as shown in the perspective view of FIG. 3A and the plan view of FIG. 3B, an electronic module 20 may have a configuration in which a general PCB terminal connector 28 having connection terminals 23 is attached to a surface of an outer layer portion 25 of the prepreg (on the upper side in FIGS. 3A and 3B).

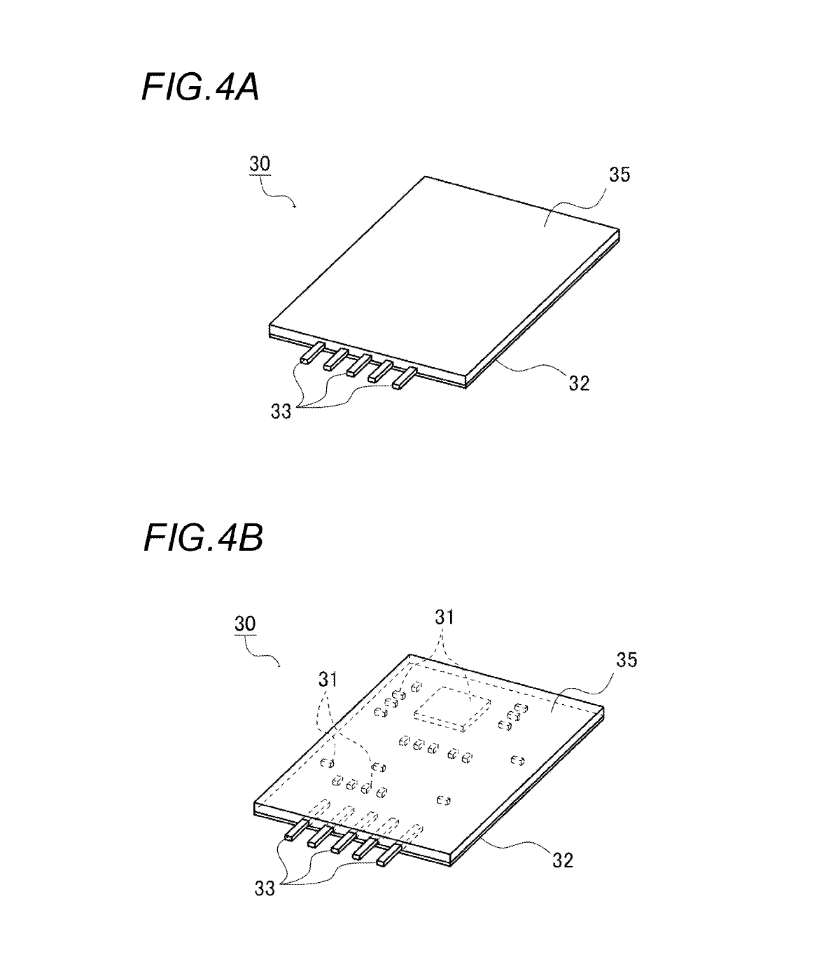

Also, as shown in the perspective view of FIG. 4A and the perspective view of FIG. 4B illustrating the inside of the electronic module of FIG. 4A by broken lines, an electronic module 30 may have a configuration in which connection terminals 33, such as metal core terminals, built in a wiring board 32 are used and parts of the connection terminals 33, electronic components 31, and the like are covered with an outer layer portion 35. Even in this case, the same effects are obtained.

The present application is based on Japanese Patent Application No. 2011-254726 filed on Nov. 22, 2011, the contents of which are incorporated herein by reference.

### INDUSTRIAL APPLICABILITY

According to the present disclosure, an electronic module with no case as an outer layer can be obtained, and such electronic module can be easily downsized.

### REFERENCE SIGNS LIST

10, 20, 30 electronic module
11, 31 electronic component
12, 22, 32 wiring board
13, 23, 33 connection terminal
15, 25, 35 outer layer portion
28 PCB terminal connector

1. An electronic component module comprising:
a wiring board on which at least one electronic component is mounted;
an outer layer portion that is made of prepreg and covers the wiring board so that all of the at least one mounted electronic component is not exposed; and
a terminal portion that is exposed from the outer layer portion to the outside and is configured to electrically connected to a mating connection member.

2. The electronic component module according to claim 1, wherein a region of the outer layer portion where the terminal portion is exposed becomes a connection structure with the mating connection member.

3. A method of manufacturing an electronic component module comprising:
providing a wiring board on which at least one electronic component is mounted, and a terminal portion which is electrically connected to the wiring board;
covering a prepreg sheet on the wiring board; and
heating the prepreg sheet to form an outer layer portion so that all of the at least one mounted electronic component is covered with a melted resin and the terminal portion for electrically connecting to a mating connection member is exposed to the outside.
